(19) United States
(12) Patent Application Publication
(10) Pub. No.: US 2019/0198993 A1
(43) Pub. Date: Jun. 27, 2019

(54) SYSTEMS AND METHODS ARE PROVIDED FOR UTILIZING RANDOMIZED ARRAY OFFSETS IN PHASED ARRAYS

(71) Applicant: Maxlinear, Inc., Carlsbad, CA (US)

(72) Inventor: Curtis Ling, Carlsbad, CA (US)

(21) Appl. No.: 16/231,457

(22) Filed: Dec. 22, 2018

Related U.S. Application Data
(60) Provisional application No. 62/609,742, filed on Dec. 22, 2017.

(51) Int. Cl. H01Q 3/26; H01Q 3/02; H03M 1/00

(52) U.S. Cl. CPC H01Q 3/267; H03M 1/004; H01Q 3/02

(57) ABSTRACT

Systems and methods are provided for utilizing randomized array offsets in phased arrays. A phased array based system may include a plurality of antenna elements arranged in two-dimensional array, and a plurality of transceiver circuits, with each transceiver circuit configured for handling transmission and reception of radio frequency (RF) signals via the plurality of antenna elements. One or more transceiver circuits in the system may be configured for applying one or more randomized adjustments to one or more particular signal processing related functions applied during the transmission and reception of RF signals. The randomized adjustments may include randomized offsets to conversions applied during processing of transmitted and/or received signals. The conversion may include one or both of digital-to-analog conversions and analog-to-digital conversions. The offsets may be randomized based on indexes identifying corresponding antenna elements.

### CLAIM OF PRIORITY

This patent application makes reference to, claims priority to and claims benefit from U.S. Provisional Patent Application Ser. No. 62/609,742, filed on Dec. 22, 2017. The above identified application is hereby incorporated herein by reference in its entirety.

### TECHNICAL FIELD

Aspects of the present disclosure relate to communications solutions. More specifically, certain implementations in accordance with the present disclosure relate to methods and systems for utilizing randomized array offsets in phased arrays.

### BACKGROUND

Various issues may exist with conventional approaches for implementing phased arrays based systems. In this regard, conventional solutions, if any existed, for handling potential noise and distortion associated with particular processing functions can be costly, inefficient, and/or ineffective.

Further limitations and disadvantages of conventional and traditional approaches will become apparent to one of skill in the art, through comparison of such systems with some aspects of the present disclosure as set forth in the remainder of the present application with reference to the drawings.

### BRIEF SUMMARY

System and methods are provided for a methods and systems for integrated force touch solutions, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example dish-based system.

FIGS. 2A and 2B illustrate an example phased array based system.

FIG. 3 illustrates an example transceiver with randomized array offsets for use in phased array based systems, in accordance with the present disclosure.

FIG. 4 illustrates a simulation of an example use scenario of an array based system without use of randomized array offsets.

FIG. 5 illustrates a simulation of an example use scenario of the same array based system of FIG. 4, but with use of randomized array offsets.

### DETAILED DESCRIPTION

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic components (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

An example system in accordance with the present disclosure may comprise a plurality of antenna elements arranged in two-dimensional array, and a plurality of transceiver circuits, with each transceiver circuit configured for handling transmission and reception of radio frequency (RF) signals via the plurality of antenna elements. One or more transceiver circuits in the system may be configured for applying one or more randomized adjustments to one or more particular signal processing related functions applied during the transmission and reception of RF signals.

In an example implementation, each of the one or more transceiver circuits may be configured for generating the one or more randomized adjustments based on corresponding one or more antenna elements in the plurality of antenna elements. In this regard, each of the one or more transceiver circuits may be configured for generating the one or more randomized adjustments as a function of indexes identifying the corresponding one or more antenna elements in the plurality of antenna elements.

In an example implementation, at least one of the one or more transceiver circuits may be configured for applying a particular randomized adjustment corresponding to a particular signal processing related function, prior to application of the particular signal processing related function; and applying a corresponding complementary adjustment after application of the particular signal processing related function.

In an example implementation, the signal processing related functions may comprise conversions applied during the transmission and reception of RF signals, such as one or both of digital-to-analog conversions and analog-to-digital conversions. In such implementation, the one or more transceiver circuits may be configured for apply randomized offsets to the conversions applied during the transmission and reception of RF signals.

In an example implementation, where the particular signal processing related function may comprise a data conversion, at least one of the one or more transceiver circuits may be configured for adding a randomized offset prior to application of the data conversion; and subtracting a same offset after application of the data conversion.

In an example implementation, at least one of the one or more randomized adjustments may be determined dynamically, such as via a controller circuit.

In an example implementation, at least one of the one or more randomized adjustments may be pre-determined and pre-programmed, such as by being stored via a storage circuit.

In an example implementation, the system may comprise one or more connectors configuring for enabling communications among the plurality of transceiver circuits, and communications within the system, to and/or from each of the plurality of transceiver circuits. The one or more connectors may comprise on-circuit based Serializer/Deserializer (SerDes) connectors

In an example implementation, at least one transceiver circuit from the plurality of transceiver circuits may be configured for controlling and/or handling two or more antenna elements from the plurality of antenna elements.

In an example implementation, the plurality of transceiver circuits may be configured for controlling operation of the plurality of antenna elements such that digital or hybrid beamforming may be enabled during the transmission and reception of RF signals via the two-dimensional array.

An example transceiver chip in accordance with the present disclosure may be configured for handling transmission and reception of radio frequency (RF) signals via one or more antenna elements from a plurality of antenna elements in a phased array based system. The transceiver chip may comprise a plurality of signal processing circuits, arranged into one or more sets of circuits, with each corresponding to one of the one or more antenna elements, and with each set of circuits being configured for handling signals transmitted and received via a corresponding antenna element of the one or more antenna elements. Each set of circuits is configured for applying one or more randomized adjustments to one or more particular signal processing related functions applied during the transmission and reception of RF signals.

In an example implementation, each set of circuits may comprise two separate sub-sets arranged for separately handling each of transmitted signals and received signals via the corresponding antenna element.

In an example implementation, each set of circuits may be configured for applying the one or more randomized adjustments based on corresponding one or more antenna elements in the plurality of antenna elements. In this regard, the randomized adjustments may be applied as a function of indexes identifying the corresponding one or more antenna elements in the plurality of antenna elements.

In an example implementation, each set of circuits may be configured for applying a particular randomized adjustment corresponding to a particular signal processing related function, prior to application of the particular signal processing related function, and applying a corresponding complementary adjustment after application of the particular signal processing related function.

In an example implementation, the signal processing related functions may comprise conversions, including one or both of digital-to-analog conversions and analog-to-digital conversions, and each set of circuits may be configured for applying randomized offsets to the conversions applied during the transmission and reception of RF signals.

In an example implementation, each set of circuits may comprise a digital-to-analog converter (DAC) circuit for applying a digital-to-analog conversion during transmission related processing, and one or more adjustment circuits for handling applying randomized offsets to the digital-to-analog conversion. The one or more adjustment circuits may comprise an offset circuit for generating a randomized offset, a combiner circuit for adding the randomized offset after the digital-to-analog conversion, and a combiner for applying a complementary adjustment based on the randomized offset before the digital-to-analog conversion.

In an example implementation, each set of circuits may comprise an analog-to-digital converter (ADC) circuit for applying an analog-to-digital conversion during reception related processing, and one or more adjustment circuits for handling applying randomized offsets to the analog-to-digital conversion. The one or more adjustment circuits may comprise: an offset circuit for generating a randomized offset, a combiner circuit for adding the randomized offset before the analog-to-digital conversion, and a combiner for applying a complementary adjustment based on the randomized offset after the analog-to-digital conversion.

In an example implementation, wherein the transceiver chip may comprise an interface circuit configured for handling communications to and/or from the transceiver chip, within the phased array based system. The interface circuit may be configured for handling Serializer/Deserializer (SerDes) based communications.

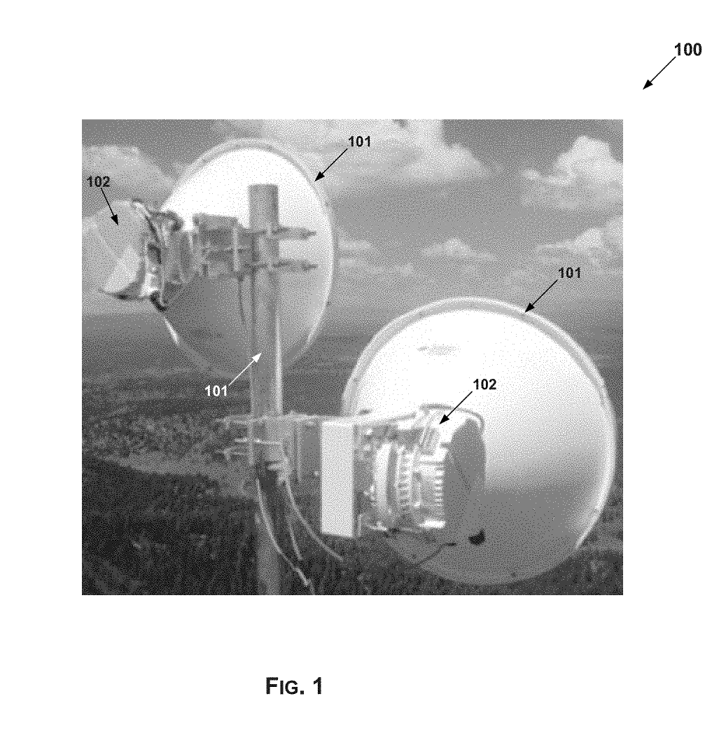

FIG. 1 illustrates an example dish-based system. Shown in FIG. 1 is an example dish-based system 100. In this regard, the dish-based system 100 may be configured for use as backhaul, such as in conventional wireless solutions (e.g., 4G networks).

The dish-based system 100 may comprise one or more dishes 101 (each being, e.g., a parabolic reflector) and corresponding boxes 102 each associated with one dish 101. The box 102 may house circuitry for facilitating transmission and reception of signals via the dish 101. For example, the box 102 may comprise circuitry for generating the radio frequency (RF) signals, for emission via the dish 102, during transmission operations, and circuitry for handling the reception of RF signals captured via the dish during reception operations. Further, the box 102 may incorporate additional component, such as a frequency duplexer (for isolating transmission and reception of signal via the common dish), a large power amplifier, etc. The boxes 102 are typically attached or coupled to the back (or base) of the dishes 101.

Because of bulkiness and weight, dish based systems are installed in limited manner—e.g., to a post 103, as shown in FIG. 1, which may be specifically constructed to support the weight of the dish-based elements. Further, the hardware components used in such systems (e.g., boxes 102) require a lot of circuitry, which further results in high power consumption and (due to certain circuit elements, such as the power amplifiers) large heat sinks.

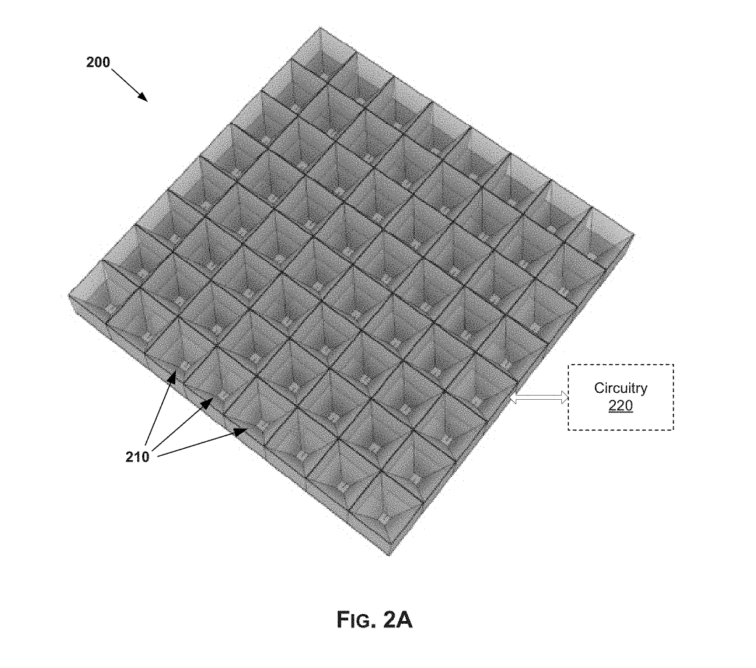

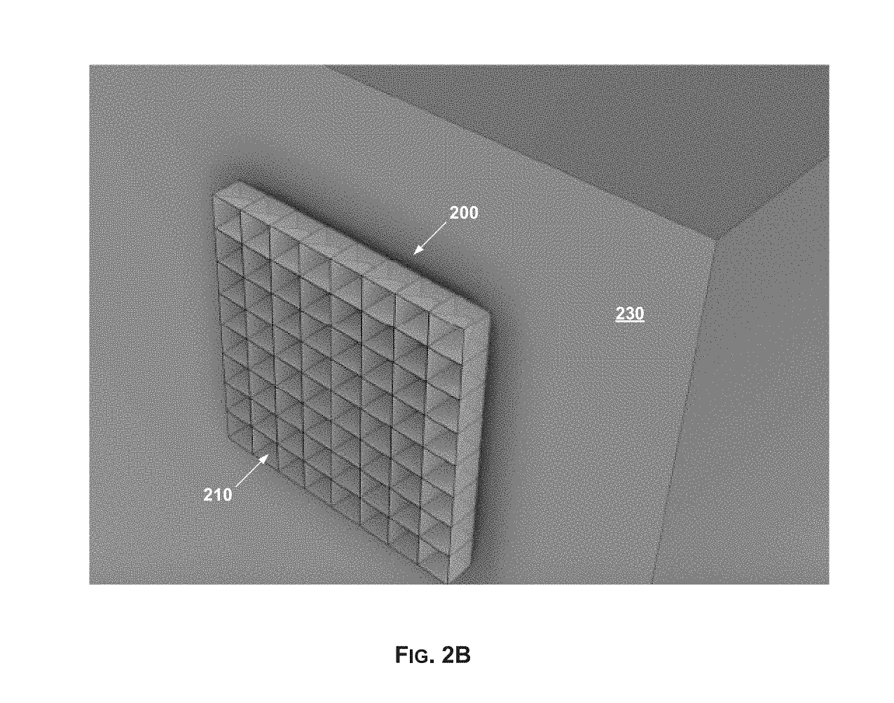

FIGS. 2A and 2B illustrate an example phased array based system. Shown in FIGS. 2A and 2B is an example phased array system 200.

The phased array system 200 may be designed and/or implemented based on use of beamforming via an array of antenna elements. In this regard, rather than using a single dish, a number of antenna elements, arranged in a 2-dimensional array, are used to transmit and receive signals. The transmission and reception of signals may be done using beamforming, which may be particularly configured for addressing possible issues (interference, etc.) and/or to provide added features, as described below. The phased array system 200 may be configured to utilize digital signals, which may allow for use of minimal circuitry. For example, the phased array system 200 may be configured for supporting digital or hybrid beamforming, as described in U.S. patent application Ser. No. 16/005,295, filed on Jun. 11, 2018, which is incorporated herein by reference in its entirety.

As shown in FIG. 2A, the phased array system 200 may comprise an array of antenna elements 210 (e.g., 64 elements, in 8×8 arrangement, as shown in the non-limiting example implementation illustrated in FIG. 2A) and circuitry 220 for handling and/or supporting transmission and reception of signals via the array of antenna elements 210. In this regard, the circuity 220 may comprise suitable circuits for performing various signal processing related functions for facilitating the transmission and reception of signals via the antenna elements 210. The circuity 220 may also be configured for performing other functions (e.g., control, storage, etc.), which may be pertinent for facilitating the transmission and reception of signals via the antenna elements 210. The circuitry 220 (or at least a portion thereof) may implemented as chip-based (e.g., system on chip (SoC), printed circuit board (PCB), etc.) circuitry incorporated into the antenna array architecture itself.

Phased array based systems, such as the phased array system 200, offer various advantages and/or improvements over conventional antenna systems, such as dish-based designs. In this regard, because of their light weight, small form factor, and use of beam steering (e.g., beamforming), phased array based systems are preferable over traditional dish-based designs. The elimination of dish and related components (e.g., the frequency duplexer, large power amplifier (“PA”), etc.) allows for installation at a wider range of sites, with lower cost of installation and operation (e.g., automatic alignment). Accordingly, phased array based systems may be installed in a more flexible manner compared to dish-based designs, allowing installation options not possible or practical with traditional designs—e.g., mounting to sides of buildings, etc. This is shown in FIG. 2B, with the phased array system 200 installed on a side wall of a building 230.

Phased array based systems generally may also have lower costs (e.g., fewer, smaller, and less expensive circuits, etc.) compared to conventional antenna systems, such as dish-based designs. Further, the use of software-defined multiband array operation adds more flexibility. For example, the elimination of certain components (e.g., duplexers) allows the array-based systems to operate across a wide frequency range. Greater link reach may be achieved for the same dish size, due to, e.g., greater transmitter power, interference suppression, etc. In addition, operations may be improved, e.g., lower operating expenditures, greater frequency reuse, lower weight, etc. Further, phased array based systems may have superior thermal dissipation characteristics. Additionally, the same core technology may be utilized for different interfaces and/or frequencies bands, allowing for common software and hardware development.

However, some issues may arise with phased arrays and use thereof. For example, one of the issues with phased arrays is the potential noise that may introduced by certain components in the system, and which may particularly be made worse because of unique architecture and features of phased arrays.

For example, phased array systems typically incorporate components that are used in performing data conversions (e.g., digital-to-analog converters (DACs) and analog-to-digital converters (ADCs)). Such components may operate in a correlated manner—e.g., performing the same step at the same time during handling of signals transmitted or received via the phased arrays. These components may exhibit nonlinear behavior, however. This may result in any errors or noise (e.g., caused by the nonlinearity of the components) to add up coherently across all elements in the phased arrays, resulting in significant degradation in overall performance.

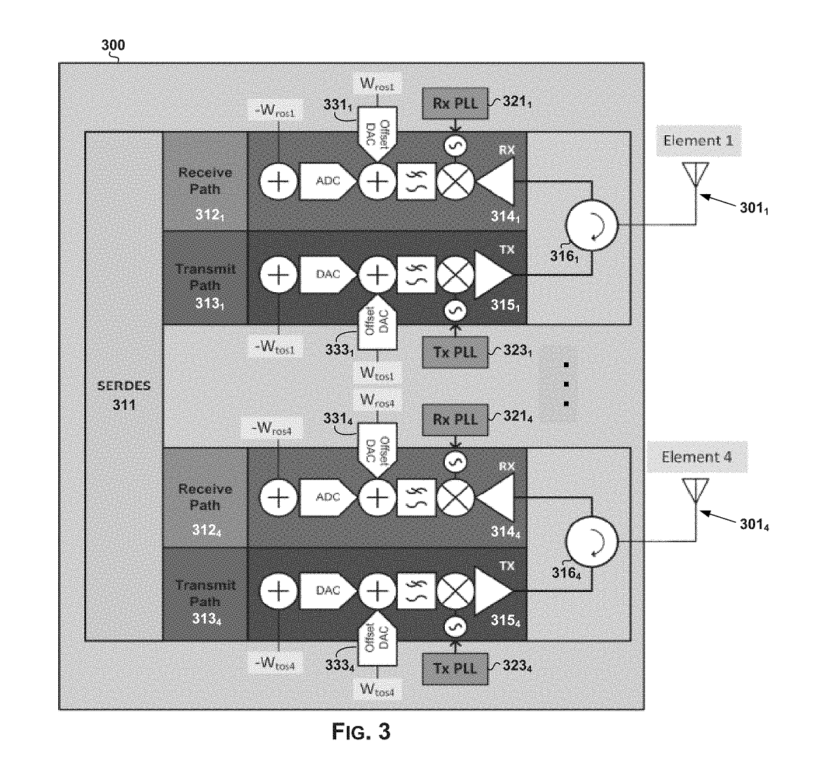

Accordingly, in various implementations in accordance with the present disclosure, phased array based systems may be configured to incorporate measures for eliminating and mitigating such errors or noise introduced due to the very nature of the phased arrays and/or characteristics of components used therein. In particular, in various example implementations, phased array systems may be configured to apply adjustments to data conversions performed therein to ensure that errors or noise introduced due to these data conversions are not added coherently, thus improving performance. This may be done, for example, by introducing randomized offsets in each of the elements, with the randomized offsets being configured to ensure eliminating or mitigating potential noise introduced as result of the data conversion. An example implementation incorporating such offset addition is described below, such as with respect to FIG. 3.

FIG. 3 illustrates an example transceiver with randomized array offsets for use in phased array based systems, in accordance with the present disclosure. Shown in FIG. 3 is an example transceiver 300, which may be utilized in phased array based systems (e.g., the phased array system 200).

In the non-limiting example implementation shown in FIG. 3, the transceiver 300 may comprise a SerDes interface circuit 311, which may be operable to handle communications to and/or from the transceiver 300, via on-chip connectors within the array architecture (e.g., with other chips, with other components sending or receiving the bit streams carried in the transmitted or received signals, etc.). Further, the transceiver 300 may comprise a plurality of transmit/receive sections, each associated with one of the antenna elements associated (connected) with this particular transceiver 300. Thus, the number of transmit/receive sections is the same as the number of associated antenna elements.

In the particular non-limiting example implementation illustrated in FIG. 3, the transceiver 300 comprises 4 transmit/receive sections, and as such it is presumably used in a phased array system comprising 4 antenna elements 301₁-301₄. It should be understood, however, that this is a non-limiting example, and that the same approach may be used in any phased array based system.

As shown in the particular non-limiting example implementation illustrated in FIG. 3, each transmit/receive section for the transceiver 300 may comprise a receive path 312, a transmit path 313, a receive front-end 314, and a transmit front-end 315. The transmit/receive sections (and sub-components thereof) may be configured to perform the required digital beamforming processing.

The transceiver 300 may also comprise components for providing timing signals. For example, as shown in FIG. 3, the transceiver 300 may comprise a plurality of dedicated radio frequency (RF) phase-locked loop (PLLs) (e.g., receive PLLs 321₁-321₄ and transmit PLLs 323₁-323₄, for providing timing (periodic) signals, for driving particular components in the transceiver 300, such as oscillators used in the transmit/receive sections for transmitting and receiving signals.

Further, because each of antenna elements 301₁-301₄ is used for both transmission and reception of signals, corresponding selection components 316₁-316₄ may be used to connect each antenna element with either the transmit-side or the receive-side of the corresponding transmit/receive section in the transceiver 300. The selection components 316₁-316₄ may be part of the transceiver 300, or may be separate from and external to the transceiver 300. The components 316₁-316₄ may be configured as switches, active circulators (as shown in FIG. 3), etc.

The transceiver 300 may be configured for utilizing offset randomization to improve performance. For example, the transceiver 300 may be configured for introducing offsets, and doing so in adaptive manner, to randomize possible errors and/or noise that may be introduced as result of data conversions performed therein. In particular, the transceiver 300 comprises circuits configured for performing data conversions, and because such components may exhibit nonlinear behavior, and because these components may operate in correlated manner—e.g., performing the same step at the same time during handling of signals transmitted or received via the phased arrays, errors or noise (e.g., caused by the nonlinearity of the components) may add up coherently across all elements—e.g., across all transmit/receive sections.

In this regard, data conversions may typically include use of (quantization) thresholds—e.g., multiple thresholds may be used during the data conversions, with each conversion step having a correspond threshold that is used to test or measure against). The thresholds, and as such the data conversions and nonlinearities introduced thereby, may be highly correlated—that is, may happen at the same place every time for the same step in each element.

Accordingly, performance may be improved by varying data conversions across the elements, to de-correlated errors or noise introduced thereby. For example, if the thresholds (or the points at which the thresholds are used) are randomize, even slightly, processing of the signals becomes a function of the element (e.g., a function of i, the element index—thus, in the implementation shown in FIG. 3, i varies from 1 to 4 (or 0 to 3)), and as a result the nonlinearity (or effects thereof) may become de-correlated. This may be done, for example, by setting or adjusting an offset for each element using a corresponding unique randomization value, which may be set based on the element index i. Thus, assuming we have identical signals being processed in each element, each element would be quantizing at a different point in the signal. In other words, by introducing randomized quantization thresholds, we change the time at which the quantization happens—that is, the time at which the threshold is tripped.

In the example implementation illustrated in FIG. 3, a plurality of offset DACs (e.g., receive offset DACs 331₁-331₄ for the receive sections, and transmit offset DACs 333₁-333₄, for the receive sections) may be used to apply offsets onto the transmit and receive sections, to randomize the data conversions performed therein, with each of these DACs applying corresponding unique offset—e.g., as shown in FIG. 3, the receive offset DAC 331₁ applying Wᵣₒₛ₁ (receive offset 1 over correlation bandwidth W), the receive offset DAC 331₄ applying Wᵣₒₛ₄ (receive offset 4), the transmit offset DAC 333₁ applying Wₜₒₛ₁ (transmit offset 1), the transmit offset DAC 333₄ applying Wₜₒₛ₄ (transmit offset 4).

As a result, the noise power is not added coherently across all of the elements because the errors introduced in the elements are uncorrelated. Further, in each of the receive sections and the transmit sections, the same offset is subtracted on the other side of the element applying data conversions (e.g., ADCs in the receive sections, DACs in the transmit sections), such as via adders. In this regard, because the same offset is added and subtracted in each transmit or receive section, the signal being processed is not effectively altered.

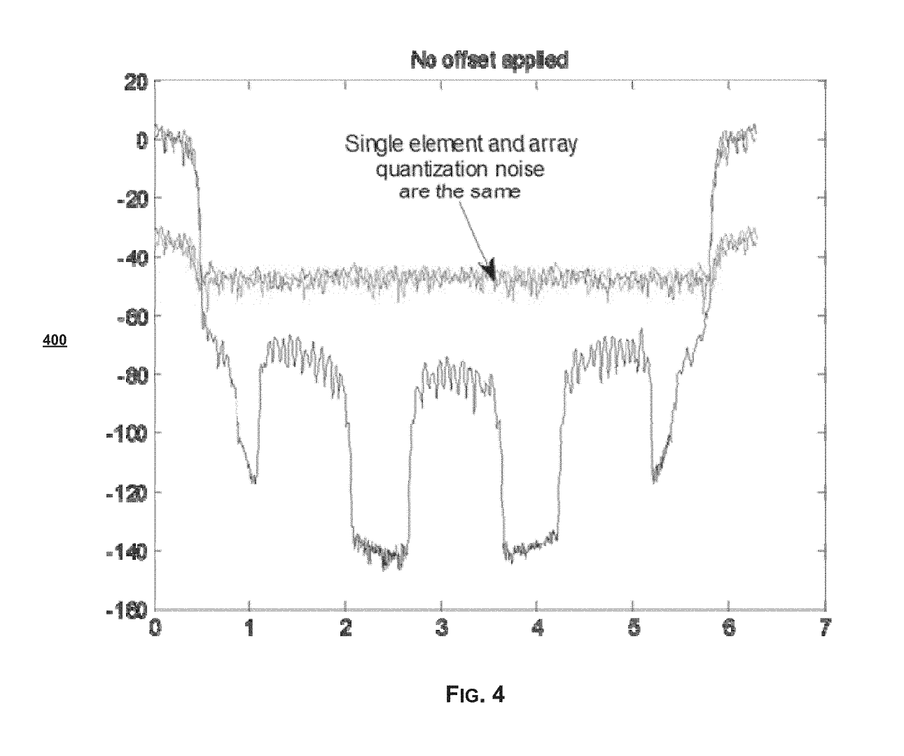

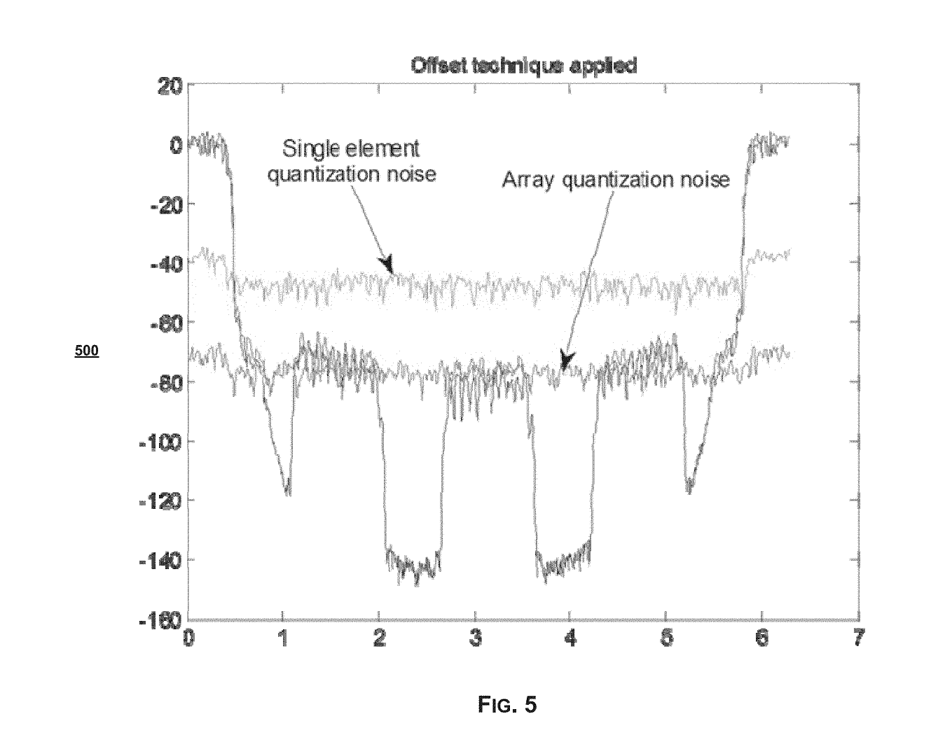

The offsets can be pre-programmed (as long as each element would have unique randomization value). The offsets may also be determined dynamically. Further, in some implementations, applying the offset may be selectively turned on or off. The improvement that may be achieved for use of offset randomization in phased array systems is illustrates in FIGS. 4 and 5.

FIG. 4 illustrates a simulation of an example use scenario of an array based system without use of randomized array offsets.

Shown in FIG. 4 is a power spectral density (PSD) chart 400, in which y-axis represents the signal power and the x-axis represents the frequency. The chart 400 corresponds to a simulation of an example use scenario in a phased array comprising 1000 elements, which is utilized without array offset randomization.

As shown in chart 400, without use of offset randomization techniques (e.g., as described with respect to FIG. 3), the quantization level of each single element and the array as a whole would be the same.

FIG. 5 illustrates a simulation of an example use scenario of the same array based system of FIG. 4, but with use of randomized array offsets.

Shown in FIG. 5 is a power spectral density (PSD) chart 500, in which y-axis represents the signal power and the x-axis represents the frequency. The chart 500 corresponds to a simulation of an example use scenario of the same phased array mentioned with respect to FIG. 4—that is, a phased array comprising 1000 elements, but with the phased array utilizing array offset randomization, such as substantially as described with respect to FIG. 3.

In this regard, as illustrated in chart 500, with the use of offset randomization techniques, a substantially improvement (e.g., ˜30 dB) may be achieved in array quantization noise relative to the quantization noise of a single element.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A system, comprising:
a plurality of antenna elements arranged in two-dimensional array; and
a plurality of transceiver circuits configured for handling transmission and reception of radio frequency (RF) signals via the plurality of antenna elements;
wherein one or more transceiver circuits are configured for applying one or more randomized adjustments to one or more particular signal processing related functions applied during the transmission and reception of RF signals.

2. The system of claim 1, wherein each of the one or more transceiver circuits is configured for generating the one or more randomized adjustments based on corresponding one or more antenna elements in the plurality of antenna elements.

3. The system of claim 2, wherein each of the one or more transceiver circuits is configured for generating the one or more randomized adjustments as a function of indexes identifying the corresponding one or more antenna elements in the plurality of antenna elements.

4. The system of claim 1, wherein:
the signal processing related functions may comprise conversions applied during the transmission and reception of RF signals, the conversions comprising one or both of digital-to-analog conversions and analog-to-digital conversions; and
the one or more transceiver circuits are configured for apply randomized offsets to the conversions applied during the transmission and reception of RF signals.

5. The system of claim 1, wherein at least one of the one or more transceiver circuits is configured for:
applying a particular randomized adjustment corresponding to a particular signal processing related function, prior to application of the particular signal processing related function; and
applying a corresponding complementary adjustment after application of the particular signal processing related function.

6. The system of claim 5, wherein the particular signal processing related function comprises a data conversion, and wherein the at least one of the one or more transceiver circuits is configured for:
adding a randomized offset prior to application of the data conversion; and
subtracting a same offset after application of the data conversion.

7. The system of claim 1, comprising a controller circuit that is configured for dynamically determining at least one of the one or more randomized adjustments.

8. The system of claim 1, comprising a storage circuit that is configured for storing pre-programmed values for at least one of the one or more randomized adjustments.

9. The system of claim 1, comprising one or more connectors configuring for enabling communications among the plurality of transceiver circuits, and communications within the system, to and/or from each of the plurality of transceiver circuits.

10. The system of claim 10, wherein the one or more connectors comprise on-circuit based Serializer/Deserializer (SerDes) connectors.

11. The system of claim 1, wherein at least one transceiver circuit from the plurality of transceiver circuits is configured to control and/or handle two or more antenna elements from the plurality of antenna elements.

12. The system of claim 1, wherein the plurality of transceiver circuits is configured for controlling operation of the plurality of antenna elements such that digital or hybrid beamforming is enabled during the transmission and reception of RF signals via the two-dimensional array.

13. A transceiver chip configured for handling transmission and reception of radio frequency (RF) signals via one or more antenna elements from a plurality of antenna elements in a phased array based system; the transceiver chip comprising:
a plurality of signal processing circuits, arranged into one or more set(s) of circuits, each corresponding to one of the one or more antenna elements;
wherein:
each set of circuits is configured for handling signals transmitted and received via a corresponding antenna element of the one or more antenna elements; and
each set of circuits is configured for applying one or more randomized adjustments to one or more particular signal processing related functions applied during the transmission and reception of RF signals.

14. The transceiver chip of claim 13, wherein each set of circuits comprises two separate sub-sets arranged for separately handling each of transmitted signals and received signals via the corresponding antenna element.

15. The transceiver chip of claim 13, wherein each set of circuits is configured for applying the one or more randomized adjustments based on corresponding one or more antenna elements in the plurality of antenna elements.

16. The transceiver chip of claim 15, wherein each set of circuits is configured for applying the one or more randomized adjustments as a function of indexes identifying the corresponding one or more antenna elements in the plurality of antenna elements.

17. The transceiver chip of claim 13, wherein each set of circuits is configured for:
applying a particular randomized adjustment corresponding to a particular signal processing related function, prior to application of the particular signal processing related function; and
applying a corresponding complementary adjustment after application of the particular signal processing related function.

18. The transceiver chip of claim 13, wherein:
the signal processing related functions comprise conversions, the conversions comprising one or both of digital-to-analog conversions and analog-to-digital conversions; and
each set of circuits is configured for apply randomized offsets to the conversions applied during the transmission and reception of RF signals.

19. The transceiver chip of claim 18, wherein each set of circuits comprises:
a digital-to-analog converter (DAC) circuit for applying a digital-to-analog conversion during transmission related processing; and
one or more adjustment circuits for handling applying randomized offsets to the digital-to-analog conversion.

20. The transceiver chip of claim 19, wherein the one or more adjustment circuits comprise:
an offset circuit for generating a randomized offset;
a combiner circuit for adding the randomized offset after the digital-to-analog conversion; and
a combiner for applying a complementary adjustment based on the randomized offset before the digital-to-analog conversion.

21. The transceiver chip of claim 17, wherein each set of circuits comprises:
an analog-to-digital converter (ADC) circuit for applying an analog-to-digital conversion during reception related processing; and
one or more adjustment circuits for handling applying randomized offsets to the analog-to-digital conversion.

22. The transceiver chip of claim 21, wherein the one or more adjustment circuits comprise:
an offset circuit for generating a randomized offset;
a combiner circuit for adding the randomized offset before the analog-to-digital conversion; and
a combiner for applying a complementary adjustment based on the randomized offset after the analog-to-digital conversion.

23. The transceiver chip of claim 13, comprising an interface circuit configured for handling communications to and/or from the transceiver chip, within the phased array based system.

24. The transceiver chip of claim 23, wherein the interface circuit is configured for handling Serializer/Deserializer (SerDes) based communications.
